(19) United States
(12) Patent Application Publication
(10) Pub. No.: US 2004/0104791 A1
(43) Pub. Date: Jun. 3, 2004

(54) Acoustic wave device and method of producing the same

(76) Inventors: Yoshio Satoh, Kawasaki (JP); Ken-ya Hashimoto, Chiba (JP)

Correspondence Address: ARENT FOX KINTNER PLOTKIN & KAHN, 1050 CONNECTICUT AVENUE, N.W., SUITE 400, WASHINGTON, DC, 20036, US

(21) Appl. No.: 10/639,646

(22) Filed: Aug. 13, 2003

(30) Foreign Application Priority Data
Aug. 13, 2002 (JP) 2002-236151

(51) Int. Cl. H03H 9/64; H03H 9/58

(52) U.S. Cl. 333/193; 333/187

(57) ABSTRACT

An acoustic wave device includes: a first substrate that has a vibration unit that generates solid vibrations based on an input electric signal, and an electrode pad unit that introduces the electric signal into the vibration unit; and a second substrate that has through holes for connecting the electrode pad unit to external electrodes. In this acoustic wave device, at least the vibration unit of the first substrate is hermetically sealed by bonding the first substrate and the second substrate to each other.

### BACKGROUND OF THE INVENTION

1. Field of the Invention

The present invention relates to an acoustic wave device and a method of producing the acoustic wave device.

2. Description of the Related Art

In communication systems today, highly stable frequency sources and filters with high selectivity need to be employed to realize highly reliable and high-speed information transmission, though there are only limited types of frequency resources.

Acoustic wave devices utilizing crystal vibrators or surface acoustic wave (SAW) filters are those devices that embody the highly stable frequency sources and filters with high selectivity. These acoustic wave devices are essential parts that determine the performances of communication devices today.

Meanwhile, in response to demands for smaller, lighter, and high performance communication devices, more and more emphasis has been put on the integration of electronic devices, with achieving a so-called “system-on-chip” being the ultimate goal. A “system-on-chip” device has all the functions integrated on a single chip.

However, it is difficult to integrate a conventional acoustic wave device with another electronic device, not to mention the fact that a “system-on-chip” device cannot be achieved with the conventional acoustic wave device. There are two reasons for this. The first reason is the difficulty of forming a practical acoustic wave device directly on a semiconductor substrate. The other reason is that a conventional acoustic wave device requires a special package that is hermetically sealed to prevent performance degradation caused by absorption of moisture and gaseous materials. These two reasons are based on the fact that an acoustic wave device is normally formed on a piezoelectric substrate and the fact that an acoustic wave device utilizes acoustic vibrations. From these facts, it is apparent that the use of acoustic wave devices has been a great hindrance to the production of smaller communication devices.

In the following, example structures of conventional packages that have been developed and utilized for surface acoustic wave devices will be described, with reference to the accompanying drawings.

FIGS. 1A and 1B are section views of a package 1000 that is the most common example structure utilizing bonding wires. This example will be hereinafter referred to as Prior Art 1.

As shown in FIG. 1A, the package 1000 of Prior Art 1 has a piezoelectric substrate 1003 placed on a substrate 1001 made of ceramics (or metal). Electrodes 1002 are attached to the substrate 1001, and a pattern 1004 of comb-like electrodes (hereinafter referred to as IDTs) is formed on the piezoelectric substrate 1003. These substrates are bonded to each other with an adhesive. The IDT pattern 1004 on the piezoelectric substrate 1003 is electrically connected to the electrodes 1002 with metal wires 1005. In this structure, a cover 1006 is welded to the side walls 1009 of the substrate 1001, as shown in FIG. 1B. Here, the space between the substrate 1001 and the cover 1006 is filled with dry nitrogen or is evacuated, and is then hermetically sealed.

With this hermetically sealed structure, Prior Art 1 prevents deterioration in the characteristics due to moisture adsorption by the surface acoustic wave device (or the IDT pattern 1004), and thus achieves sufficiently high reliability. The package of Prior Art 1, however, has a problem of being much larger than the piezoelectric substrate 1003.

To solve this problem with Prior Art 1, a package structure shown in FIGS. 2A and 2B, which is called a “flip chip” structure, has been suggested. This example structure will be hereinafter referred to as Prior Art 2.

As shown in FIG. 2A, the package 2000 of Prior Art 2 has a piezoelectric substrate 2003 placed on a substrate 2001 that is made of ceramics (or metal). Electrodes 2002 are attached to the substrate 2001, and an IDT pattern 2004 is formed on the piezoelectric substrate 2003. Here, the IDT pattern 2004 faces the substrate 2001. The substrate 2001 and the piezoelectric substrate 2003 are electrically connected to each other with metal bumps 2008 or the likes. The metal bumps 2008 also function as means to secure the piezoelectric substrate 2003. In this structure, a cover 2006 is welded to the side walls 2009 of the substrate 2001, as shown in FIG. 2B.

By employing the metal bumps 2008, instead of the metal wires 1005 for bonding, the space saved for the metal wires 1005 is eliminated in Prior Art 2, so that the package 2000 can be restricted to a size only slightly larger than the piezoelectric substrate 2003. In Prior Art 2, the height of the package 2000 is also much smaller than that of the Prior Art 1.

To realize an even smaller package, a structure called a “chip-size package”, shown in FIGS. 3A and 3B, has been developed. This example structure will be hereinafter referred to as Prior Art 3.

As shown in FIG. 3A, the package 3000 of Prior Art 3 has a piezoelectric substrate 3003 placed on a substrate 3001 that does not have a side wall and is made of ceramics (or metal). An IDT pattern 3004 is formed on the piezoelectric substrate 3003, and the IDT pattern 3004 faces the substrate 3001. The substrate 3001 and the piezoelectric substrate 3003 are electrically connected to each other with metal bumps 3008 or the likes. The metal bumps 3008 also function as means to secure the piezoelectric substrate 3003. Further, a protection layer is deposited on the surface of the piezoelectric substrate 3003. In this structure, the substrate 3001 and a cover 3006 are entirely covered and hermetically sealed with a mold 3010 that is made of plastic or resin, as shown in FIG. 3B.

With this structure, Prior Art 3 can provide the package 3000 having almost the same size as that of the piezoelectric substrate 3003.

Although the package of the acoustic wave device can be made as small as the chip size in Prior Art 3, the mold made of plastic or resin cannot completely shut out the air (especially moisture). This results in poor reliability in terms of moisture absorption. Because of this, it is difficult to maintain sufficient reliability in a case where a module is formed by arranging the package and some other semiconductor chip on one substrate. In such a case, it is necessary to employ an expensive hermetic seal for the entire module including the acoustic wave device.

### SUMMARY OF THE INVENTION

It is therefore an object of the present invention to provide an acoustic wave device in which the above disadvantage is eliminated.

A more specific object of the present invention is to provide an acoustic wave device that is hermitically sealed without an increase in size.

Another specific object of the present invention is to provide a method of producing a small and highly reliable acoustic wave device that can input and output electric signals without the use of metal wires or the likes.

The above objects of the present invention are achieved by an acoustic wave device comprising: a first substrate that has a vibration unit that generates solid vibrations based on an input electric signal, and an electrode pad unit that introduces the electric signal into the vibration unit; and a second substrate that has through holes for connecting the electrode pad unit to external electrodes, at least the vibration unit of the first substrate being hermetically sealed by bonding the first substrate and the second substrate to each other. With this structure, it becomes possible to input and output electrical signals without any metal wires and to provide a hermetically sealed SAW device without any increase in size.

The above objects of the present invention are also achieved by an acoustic wave device comprising: a first substrate that has a vibration unit that generates solid vibrations based on an input electric signal; a second substrate that is bonded to the upper face of the first substrate; and a third substrate that is bonded to the lower face of the first substrate, the second substrate or the third substrate having a through hole for electrically connecting the first substrate to an external electrode, and at least the vibration unit of the first substrate being hermetically sealed by bonding the second substrate and the third substrate to the first substrate.

The above objects of the present invention are also achieved by a method of producing an acoustic wave device, comprising the step of bonding a second substrate to a first substrate, the first substrate having a vibration unit that generates solid vibrations based on input electric signal and an electrode pad unit that introduces the electric signal into the vibration unit, the second substrate having through holes for electrically connecting the electrode pad unit to external electrodes, and the second substrate being bonded to a face of the first substrate on which the vibration unit is formed, to thereby hermetically seal at least the vibration unit of the first substrate.

The above objects of the present invention are also achieved by a method of producing an acoustic wave device, comprising the steps of: bonding a second substrate onto the upper face of a first substrate on which a vibrator is formed, the vibrator generating solid vibrations based on an input electric signal; and bonding a third substrate to the lower face of the first substrate, the third substrate having a through hole for connecting the vibrator to an external electrode, at least the vibrator of the first substrate being hermetically sealed through the foregoing steps.

### BRIEF DESCRIPTION OF THE DRAWINGS

Other objects, features and advantages of the present invention will become more apparent from the following detailed description when read in conjunction with the accompanying drawings, in which:

FIGS. 1A and 1B are section views of the structure of a package in accordance with Prior Art 1;

FIGS. 2A and 2B are section views of the structure of a package in accordance with Prior Art 2;

FIGS. 3A and 3B are section views of the structure of a package in accordance with Prior Art 3;

FIG. 4A is a top view of the piezoelectric substrate of a chip on which a comb-like electrode (IDT) pattern is formed in accordance with a first embodiment of the present invention;

FIG. 4B is a top view of the cover of the chip in accordance with the first embodiment;

FIG. 4C is a top view of the chip formed by bonding the piezoelectric substrate and the cover to each other in accordance with the first embodiment;

FIGS. 5A through 5D are section views illustrating the production process of a package that is formed by combining the chip shown in FIGS. 4A through 4C with a circuit board;

FIG. 6A is a top view of the piezoelectric substrate of a chip on which a comb-like electrode (IDT) pattern is formed in accordance with a second embodiment of the present invention;

FIG. 6B is a top view of the cover of the chip in accordance with the second embodiment;

FIG. 6C is a top view of the chip formed by bonding the piezoelectric substrate and the cover to each other in accordance with the second embodiment;

FIGS. 7A through 7E are section views illustrating the production process of a package that is formed by combining the chip shown in FIGS. 6A through 6C with a circuit board;

FIG. 8A is a top view of the upper cover of a chip in accordance with a third embodiment of the present invention;

FIG. 8B is a top view of the bulk wave vibrator of the chip in accordance with the third embodiment;

FIG. 8C is a top view of the lower cover of the chip in accordance with the third embodiment;

FIG. 8D is a top view of the chip formed by bonding the upper cover and the lower cover to the bulk wave vibrator in accordance with the third embodiment;

FIGS. 9A through 9D are section views illustrating the production process of a package that is formed by combining the chip shown in FIGS. 8A through 8D with a circuit board; and

FIGS. 10A through 10D illustrate the production process of chips in accordance with a fourth embodiment of the present invention.

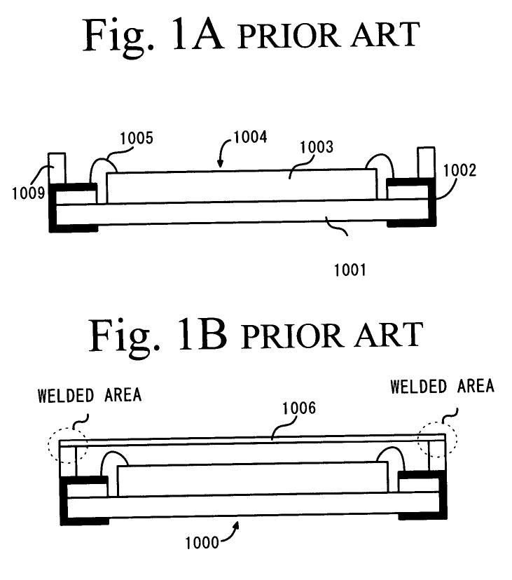

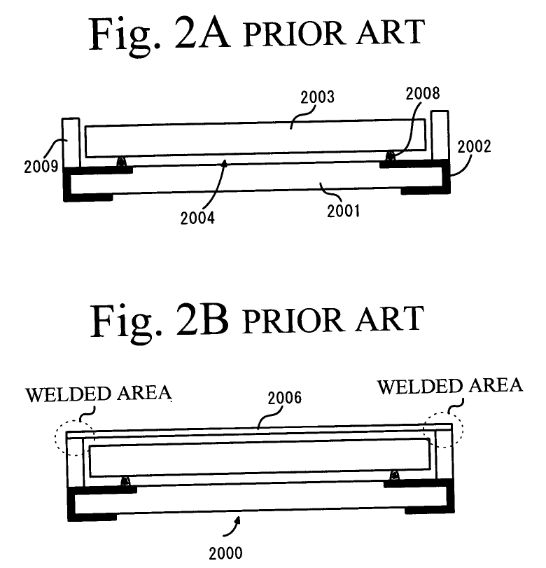

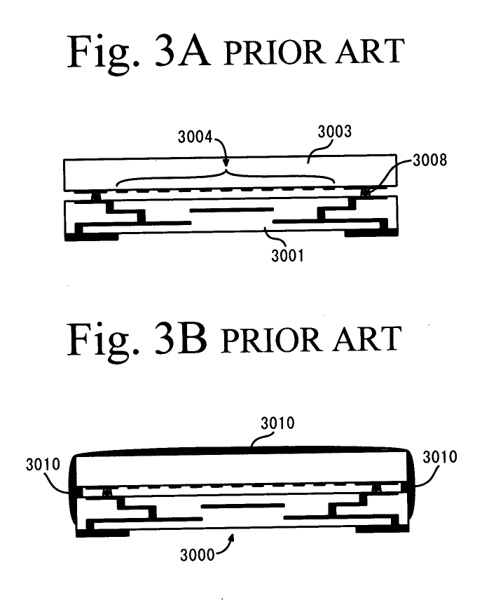

### DESCRIPTION OF THE PREFERRED EMBODIMENTS

The following is a description of preferred embodiments of the present invention, with reference to the accompanying drawings.

### FIRST EMBODIMENT

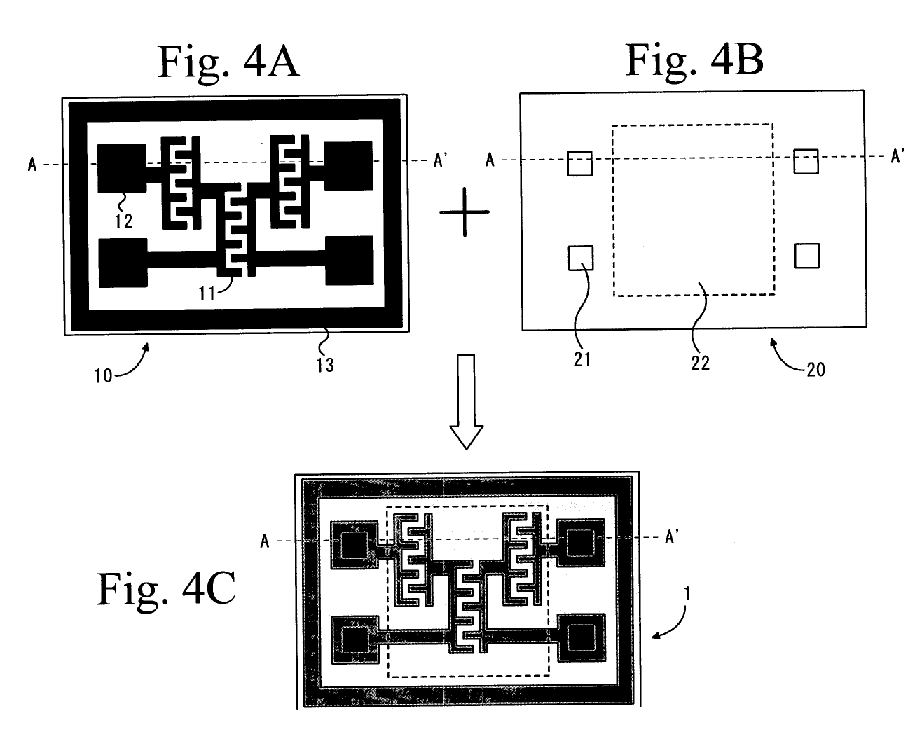

Referring to FIGS. 4A through 4C, a first embodiment of the present invention will be first described. FIGS. 4A through 4C illustrate the structure of a chip 1 into which a surface acoustic wave device in accordance with this embodiment is incorporated. More specifically, FIG. 4A is a top view of a piezoelectric substrate 10 on which a comb-like electrode (IDT) pattern 11 is formed. FIG. 4B is a top view of a cover 20. FIG. 4C is a top view of the chip 1 formed by bonding the piezoelectric substrate 10 and the cover 20 to each other.

As shown in FIG. 4A, the IDT pattern 11, an electrode pad unit 12, and a peripheral metal layer 14, are formed on the piezoelectric substrate 10 that is produced by processing a semiconductor wafer. The IDT pattern 11 is part of a vibration unit that generates solid vibrations based on input electric signals. The electrode pad unit 12 electrically connects the IDT pattern 11 to the outside so as to introduce the electric signals. The peripheral metal layer 13 surrounds the IDT pattern 11 and the electrode pad unit 12. In this structure, the IDT pattern 11 and the electrode pad unit 12 constitute a surface acoustic wave (SAW) filter. Accordingly, the peripheral metal layer 13 does not have an electric connection with the IDT pattern 11 and the electrode pad unit 12. The peripheral metal layer 13 at least has such a shape as to surround the IDT pattern 11 that forms the vibration unit. The IDT pattern 11, the electrode pad unit 12, and the peripheral metal layer 13, are made of aluminum (Al), gold (Au), or the like.

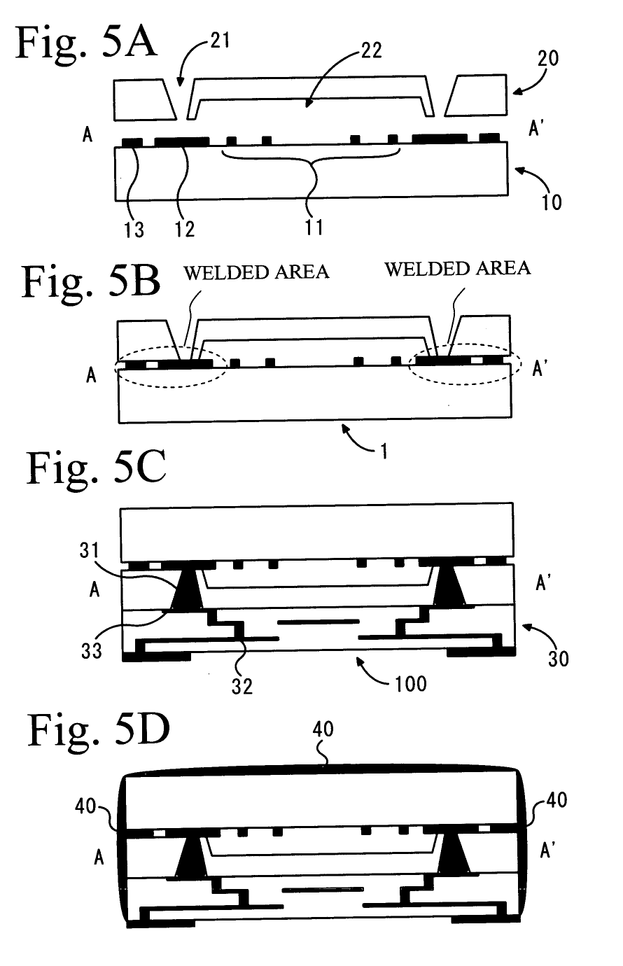

As shown in FIG. 4B, the cover 20, which functions in cooperation with the electrode pad unit 12 and the peripheral metal layer 13 so as to hermetically seal the IDT pattern 11, has through holes 21 that electrically connect the electrode pad unit 12 to external wires 32 shown in FIG. 5C, and a hollow portion 22 that maintains an internal space for allowing the IDT pattern 11 to vibrate. The hollow portion 22 is formed on the side facing the piezoelectric substrate 10, and has such a depth as not to reach the IDT pattern 11 that minutely vibrates. The depth may be several microns to 90 microns, for example. The cover 20 is produced by processing an insulating wafer made of glass, ceramics, or silicon (Si), for example.

The piezoelectric substrate 10 that serves as a first substrate and the cover 20 that serves as a second substrate are put on top of each other, so that the chip 1 shown in FIG. 4C is formed.

Referring next to FIGS. 5A through 5D, the production process of a package 100 that is an acoustic wave device formed by combining the chip 1 with a circuit board 30 will be described. FIGS. 5A through 5D are section views taken along the lines A-A′ of FIGS. 4A through 4C.

In the production process of the package 100 in accordance with this embodiment, an insulating substrate made of glass, ceramics, or silicon (Si), for example, is first processed to produce the cover 20 (the second substrate) having the hollow portion 22 on the surface and the through holes 21 for connecting electrodes, as shown in FIG. 5A. In the next step, the cover 20 is bonded to the piezoelectric substrate 10 (the first substrate) on which a SAW filter of a surface acoustic wave device is formed, as shown in FIG. 5B. Here, positioning is performed so that the hollow portion 22 of the cover 20 is located over the IDT pattern 11 that generates mechanical minute vibrations, and that the through holes 21 of the cover 20 are located over the electrodes of the electrode pad unit 12. The hollow in the chip 1 formed by the hollow portion 22 is filled with dry nitrogen or is evacuated so as to eliminate adverse influence on the propagation of surface acoustic waves.

In bonding the cover 20 to the piezoelectric substrate 10, a metal material (the peripheral metal layer 13) is directly bonded to glass, ceramics, or silicon (the cover 20), so that the hollow portion is hermetically sealed and completely shut off from the external air.

In this embodiment, the defect in the hermetic seal of the hollow portion due to the gap between the piezoelectric substrate 10 and the cover 20 bonded to each other, is solved by welding the cover 20 to the peripheral metal layer 13 of the same thickness as that of the electrode pad unit 12, as the gap between the piezoelectric substrate 10 and the cover 20 has the width equivalent to the thickness of the electrode pad unit 12. However, it is also possible to employ a structure in which the hollow portion is sealed with a glass frit or an adhesive made of an ultraviolet curing resin, for example, which can efficiently shut off the air (especially moisture). By filling the gap equivalent to the thickness of the electrode pad unit 12 with the above material, which is soft before the solidification, the hollow portion of the chip 1 can be hermitically sealed. Since the thickness of the electrode pad unit 12 is very small, the hermitic seal can be surely maintained by filling the gap with an adhesive or a glass frit. With this structure, the size of the chip 1 can be reduced by the size of the peripheral metal layer 13.

It is also possible to employ other structures. For example, a metal film may be formed beforehand in an area on the cover 20 that is brought into contact with the electrode pad unit 12 and the peripheral metal layer 13, so that metal welding can be performed between the metal film and the electrode pad unit 12 and the peripheral metal layer 13. Also, the bonding areas of the piezoelectric substrate 10 and the cover 20 may be welded to each other.

After the piezoelectric substrate 10 and the cover 20 are bonded to each other as described above, metal bumps 31 made of gold or solder, for example, are put into the through holes 21 of the cover 20, for example, as shown in FIG. 5C. The through holes 21 are sealed with the metal bumps 31, and the hermetic seal of the hollow portion is strengthened.

In the above manner, the hollow portion of the chip 1 is hermetically sealed. Accordingly, the chip 1 can be regarded as an independent device (meaning that there is no need to prepare a special environment, such as a vacuum environment or a dry N₂ atmosphere, for the chip 1). In a case where hybrid mounting is performed with some other semiconductor device (made of Si or GaAs), it is also unnecessary to take trouble to hermetic seal the device including the chip 1. Accordingly, the flexibility in designing the device can be greatly increased.

Further, the packaging circuit board 30 having electrodes 33 attached thereto is bonded to the side of the cover 20 on which the metal bumps 31 are mounted, as shown in FIG. 5C. Here, the metal bumps 31 are brought into contact with the electrodes 33, so that the electrode pad unit 12 is electrically connected to the external wires 32. Thus, the package 100 is completed.

In this embodiment, the package 100 may be covered with a mold 40 made of plastic or resin, for example, as shown in FIG. 5D. By doing so, the hermetic seal is further strengthened. In that case, the area to be covered with the mold 40 may be the entire device, or only the bonding areas of the substrates. In this manner, a surface acoustic wave device can be put into a very small package, while reliability is maintained in terms of moisture absorption.

Although a SAW (Surface Acoustic Wave) filter is employed in the chip 1 in this embodiment, any other device having a vibration unit that needs to be hermetically sealed can be employed in the present invention. Examples of those devices include a SAW resonator, a FBAR (Film Bulk Acoustic Resonator), and a FBAR filter. In a case of employing one of those devices, the first substrate should be made of silicon (Si), gallium arsenide (GaAs), or glass.

The circuit board 30, which serves as a third substrate, is a ceramic substrate for packaging in this embodiment. However, it is also possible to employ a silicon substrate or a GaAs substrate into which an active device is incorporated.

As described above, this embodiment provides an acoustic wave device that can be immediately used as an independent component. This embodiment also provides a method of producing such an acoustic wave device. Thus, a smallest possible device with high reliability can be obtained.

Also, with a semiconductor substrate made of silicon or GaAs, instead of a ceramic packaging substrate, an acoustic wave device can be integrated with a semiconductor circuit. With such a structure, a “system-on-chip” device can be readily realized.

### SECOND EMBODIMENT

Next, a second embodiment of the present invention will be described in detail, with reference to the accompanying drawings. This embodiment aims to simplify the structure and the production process through elimination of the hollow portion 22 of the cover 20 that is the second substrate. This embodiment also aims to increase the mechanical strength of the cover 20 and to reduce the production costs.

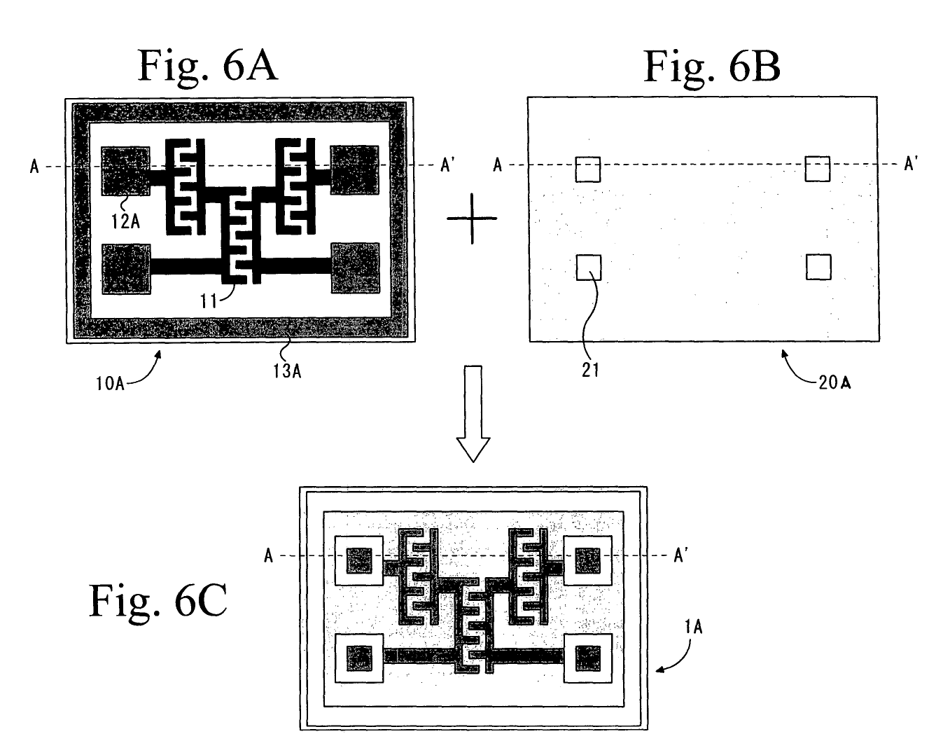

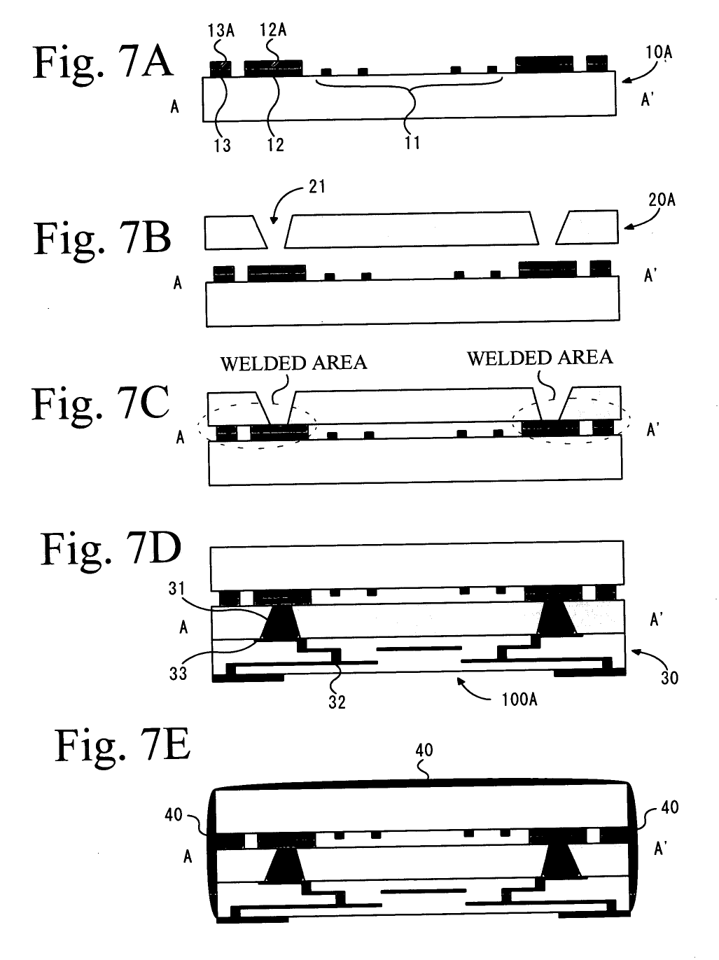

Referring now to FIGS. 6A through 7E, the structure of a chip 1A of this embodiment will be described in detail. FIGS. 6A through 6C illustrate the structure of the chip 1A. More specifically, FIG. 6A is a top view of a piezoelectric substrate 10A on which an IDT pattern 11 is formed. FIG. 6B is a top view of a cover 20A. FIG. 6C is a top view of the chip 1A formed by bonding the piezoelectric substrate 10A and the cover 20A to each other.

The piezoelectric substrate 10A shown in FIG. 6A has thin metal films 12A and 13A formed on an electrode pad unit 12 and a peripheral metal layer 13 that are the same as those of the piezoelectric substrate 10 shown in FIG. 4A. The cover 20A shown in FIG. 6B has the same structure as the cover 20 shown in FIG. 4B, except that the hollow portion 22 is removed.

The metal films 12A and 13A each has a thickness of several microns to 90 microns, for example, and constitute a hollow portion for allowing the IDT pattern 11 to vibrate after the piezoelectric substrate 10A and the cover 20A are bonded to each other. The metal films 12A and 13A can be formed by depositing metal films through plating, vapor deposition, sputtering, or the like, after the IDT pattern 11, which forms the vibration unit, and its surrounding area are covered with a resist or the like.

In this manner, the electrode pad unit 12 and the peripheral metal layer 13 are made thicker than the IDT pattern 11, so that a hollow portion spacious enough to allow the IDT pattern 11 to vibrate can be formed as in the first embodiment.

The bonding for creating a hermetic seal is performed between the insulating face of the cover 20A (or the metal face of the cover 20A, if a metal film were deposited thereon) and the metal faces of the metal films 12A and 13A. The other parts of this embodiment are the same as the corresponding parts of the structure of the first embodiment, and therefore, explanation of them is omitted herein.

Referring now to FIGS. 7A through 7E, the production process of a package 100A formed by combining the chip 1A with a circuit board 30 will be described. FIGS. 7A through 7E are section views taken along the lines A-A′ of FIGS. 6A through 6C.

First, as shown in FIG. 7A, a resist is formed on the electrode pad unit 12 and the peripheral metal layer 13, which are the same as those of the piezoelectric substrate 10 of the first embodiment. Plating, vapor deposition, sputtering, or the like is then performed to deposit the metal films 12A and 13A. In this manner, the piezoelectric substrate 10A is formed. The other parts of the structure are the same as the corresponding parts of the first embodiment, and therefore, explanation of them is omitted herein.

Next, as shown in FIG. 7B, an insulating wafer, made of a material such as glass, ceramics, and silicon (Si), is processed to produce the cover 20A (the second substrate) having the through holes 21 for connecting electrodes. The cover 20A is then bonded onto the face of the piezoelectric substrate 10A (the first substrate) on which the IDT pattern 11 is formed, as shown in FIG. 7C. Here, positioning is performed so that the through holes 21 of the cover 20A are located over the metal films 12A on the electrode pad unit 12. By doing so, a hollow portion having a depth corresponding to the thickness of each of the metal films 12A and 13A is formed above the IDT pattern 11 that generates mechanical minute vibrations. Here, the hollow portion of the chip 1A formed between the piezoelectric substrate 10A and the cover 20A is filled with dry nitrogen or is evacuated, so as not to have adverse influence on the propagation of surface acoustic waves.

In bonding of the cover 20A to the piezoelectric substrate 10A, direct bonding is performed between metal (the peripheral metal layer 13) and glass, ceramics, or silicon (the cover 20), as in the first embodiment.

It is also possible to employ a structure in which a metal film is formed beforehand in such an area on the cover 20A as to be in contact with the metal films 12A and 13A, and bonding between metal films is performed. Alternatively, the bonding areas of the piezoelectric substrate 10A and the cover 20A may be welded to each other. The other steps in the production process of this embodiment are the same as the corresponding steps in the production process of the first embodiment, and therefore, explanation of them is omitted herein.

With the above structure, forming the hollow portion 22 in the cover becomes unnecessary. Thus, the production process is simplified, the mechanical strength of the cover is increased, and the production costs are reduced.

### THIRD EMBODIMENT

Next, a third embodiment of the present invention will be described in detail, with reference to the accompanying drawings. In this embodiment, a bulk wave vibrator such as a crystal vibrator is employed, instead of the surface acoustic wave device of the first embodiment.

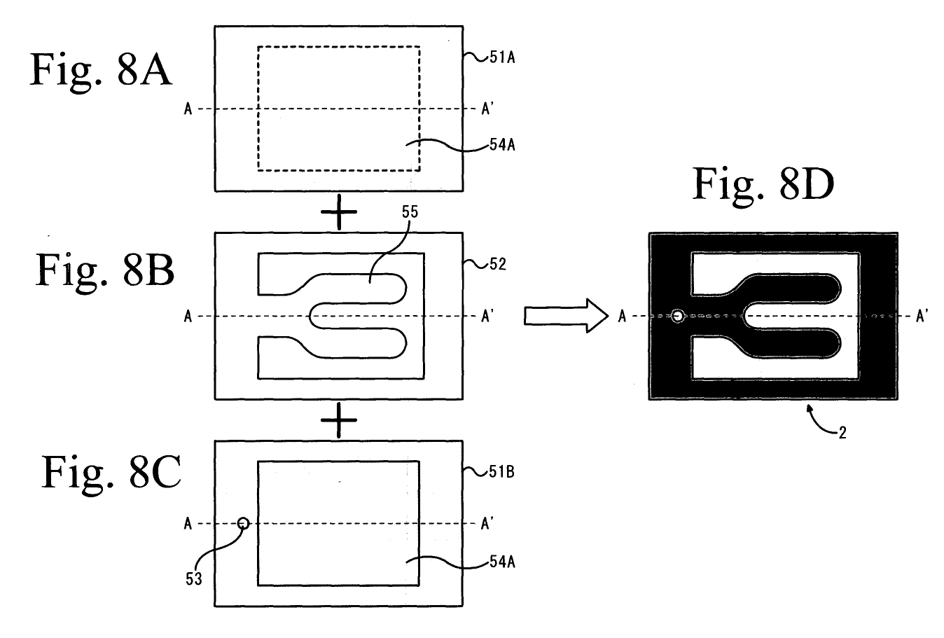

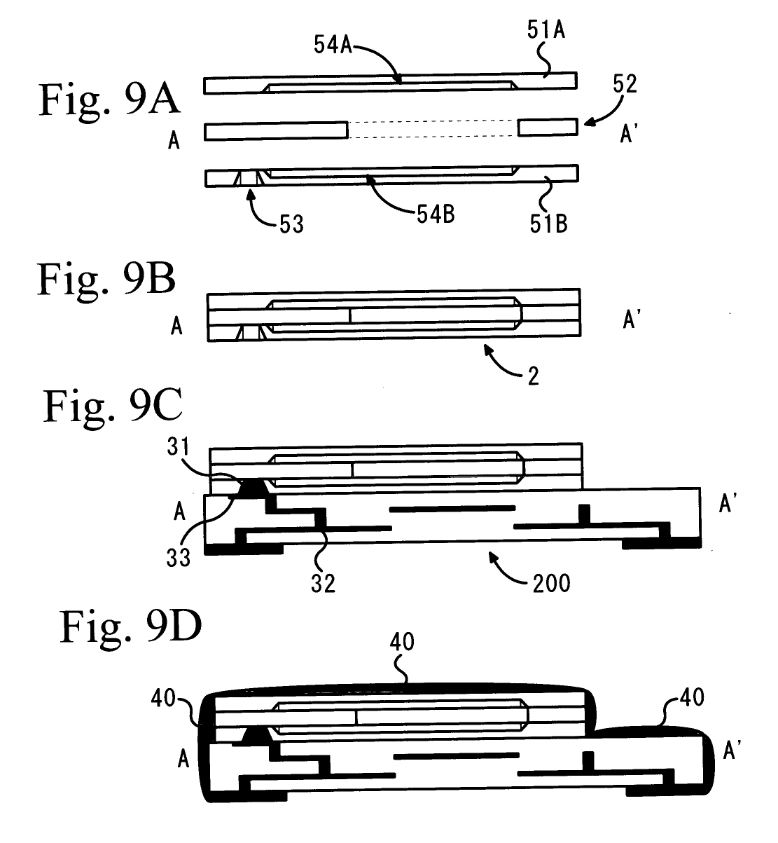

Referring to FIGS. 8A through 9D, the structure of a chip 2 of this embodiment will be described in detail. FIGS. 8A through 8D illustrate the structure of the chip 2. More specifically, FIG. 8A is a top view of an upper cover 51A that serves as the second substrate. FIG. 8B is a top view of a bulk wave vibrator 52 that serves as the first substrate. FIG. 8C is a top view of a lower cover 51B that serves as the third substrate. FIG. 8D is a top view of the chip 2 formed by bonding the upper cover 51A and the lower cover 51B to the bulk wave vibrator 52.

The upper cover 51A shown in FIG. 8A has a groove (a hollow portion 54A) for allowing a vibrator 55 to vibrate on the side to be in contact with the bulk wave vibrator 52. Likewise, the lower cover 51B shown in FIG. 8C has a groove (a hollow portion 54B) formed on the side to be in contact with the bulk wave vibrator 52. Further, a through hole 53 for electrically connecting the bulk wave vibrator 52 to an external wire is formed in the lower cover 52B. The bulk wave vibrator shown in FIG. 8B has the vibrator 55 that is formed by patterning a semiconductor wafer.

In this structure, the hollow portions 54A and 54B each has such a depth as to allow the vibrator 55 to vibrate. The depth is several microns to 90 microns, for example. The three substrates are stacked and bonded to one another in the same manner as in the first embodiment, so as to obtain the chip 2 shown in FIG. 8D. The other parts of this embodiment are the same as the corresponding parts of the first embodiment, and therefore, explanation of them is omitted herein.

Referring now to FIGS. 9A through 9D, the production process of a package 200 formed by combining the chip 2 with a circuit board 30 will be described. FIGS. 9A through 9D are section views taken along the lines A-A′ of FIGS. 8A through 8D.

First, as shown in FIG. 9A, the insulating upper and lower covers 51A and 51B (the second and third substrates) having the hollow portions 54A and 54B, respectively, are prepared. The upper cover 51A and the lower cover 51B are then bonded to the upper and lower faces of the bulk wave vibrator 52 (the first substrate), as shown in FIG. 9B. The bonding technique is the same as that employed in the first embodiment. The through hole 53 for inputting and outputting electric signals is formed in the lower cover 51B.

After the chip 2 is formed by sandwiching the bulk wave vibrator 52 between the insulating upper and lower covers 51A and 51B, a metal bump 31 made of gold or solder, for example, is put into the through hole 53, and face-down bonding is then performed, as shown in FIG. 9C. By doing so, the chip 2 is electrically connected to the circuit board 30 that serves as a fourth substrate. In this manner, the package 200 of a very small and highly reliable crystal vibrator can be obtained.

The package 200 may be covered with a mold 40, as shown in FIG. 9D. The area to be covered with the mold 40 may be the entire package 200 or only the bonding areas of the substrates. With the mold 40, a very small device package can be realized, while maintaining high reliability in terms of moisture absorption. The other steps in the production process of this embodiment are the same as the corresponding steps of the first embodiment, and therefore, explanation of them is omitted herein.

### FOURTH EMBODIMENT

A fourth embodiment of the present invention will now be described, with reference to the accompanying drawings. This embodiment aims to collectively produce hermetically sealed chips or packages of any of the foregoing embodiments.

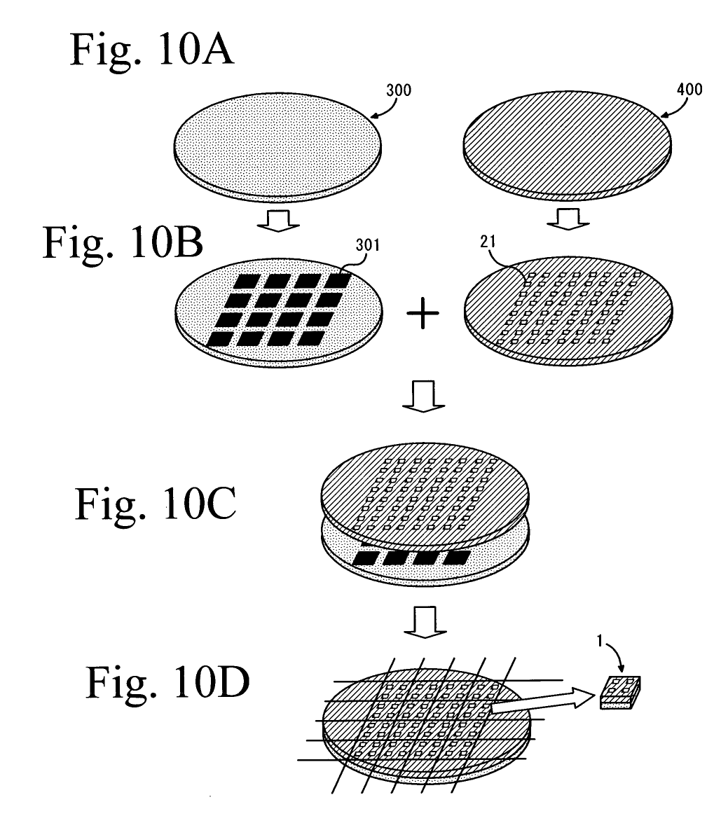

Referring to FIGS. 10A through 10D, the production process of chips in accordance with this embodiment will be described in detail. In the example case described below, chips 1 of the first embodiment are collectively produced.

First, as shown in FIG. 10A, a semiconductor wafer 300 and an insulating wafer 400 are prepared. SAW filters 301 in the form of an Al or Au electrode pattern are then formed on the semiconductor wafer 300 that serves as the first substrate, as shown in FIG. 10B. Meanwhile, through holes 21 are formed in the insulating wafer 400 that serves as the second substrate. More specifically, the through holes 21 are formed at the locations corresponding to the electrode pad units 12 and the peripheral metal layers 13 of the SAW filters 301, in compliance with the shapes of the SAW filters 301.

The two wafers 300 and 400 are then positioned to face each other, and are bonded to each other (by the same technique as that employed in the first embodiment, for example), as shown in FIG. 10C. If metal-to-metal bonding is employed, a metal film should be formed beforehand at a location corresponding to the bonding area on the insulating wafer 400 that serves as the cover.

After being bonded to each other, the wafers 300 and 400 are cut into a number of chips 1, as shown in FIG. 10D. Here, metal bumps may be formed in the through holes 21 in the insulating wafer 400 immediately after the semiconductor wafer 300 and the insulating wafer 400 are bonded to each other. In that case, the wafers 300 and 400 are face-down bonded to a wafer having circuit boards 30 formed thereon, and are then cut into packages 100.

Through the above production process, a large number of hermetically sealed chips or packages can be produced in a much simpler manner than in a case where positioning and bonding are performed for each individual chip. Although SAW filters are employed in this embodiment, it is also possible to employ other acoustic wave devices, instead of the SAW filters.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An acoustic wave device comprising:
a first substrate that has a vibration unit that generates solid vibrations based on an input electric signal, and an electrode pad unit that introduces the electric signal into the vibration unit; and
a second substrate that has through holes for connecting the electrode pad unit to external electrodes,
at least the vibration unit of the first substrate being hermetically sealed by bonding the first substrate and the second substrate to each other.

2. The acoustic wave device as claimed in claim 1, wherein:
the first substrate further includes a peripheral metal layer that surrounds at least the vibration unit; and
the vibration unit is hermetically sealed by bonding the second substrate to the peripheral metal layer and/or the electrode pad unit.

3. The acoustic wave device as claimed in claim 1, wherein the second substrate has a hollow for allowing solid vibrations of the vibration unit.

4. The acoustic wave device as claimed in claim 1, wherein the electrode pad unit and/or the peripheral metal layer are thicker than electrodes of the vibration unit.

5. The acoustic wave device as claimed in claim 1, wherein at least the outer periphery of the bonding area between the first substrate and the second substrate is covered with a mold made of a predetermined plastic or resin material.

6. The acoustic wave device as claimed in claim 1, wherein the second substrate is an insulating substrate.

7. The acoustic wave device as claimed in claim 1, wherein:
the first substrate is a piezoelectric substrate; and
the vibration unit is a surface acoustic wave resonator or a surface acoustic wave filter.

8. The acoustic wave device as claimed in claim 1, wherein:
the first substrate is made of silicon or gallium arsenide; and
the vibration unit is a film bulk acoustic resonator or a film bulk acoustic resonator filter.

9. The acoustic wave device as claimed in claim 1, wherein the second substrate is made of at least one of silicon, glass, ceramics, and plastic.

10. The acoustic wave device as claimed in claim 1, further comprising
a third substrate having wires for transmitting the electric signal,
wherein
the second substrate is face-down bonded to the third substrate, and the wires are electrically connected to the electrode pad unit by virtue of metal bumps that are put into the through holes.

11. The acoustic wave device as claimed in claim 10, wherein the third substrate is made of ceramics or is formed by a semiconductor chip.

12. An acoustic wave device comprising:
a first substrate that has a vibration unit that generates solid vibrations based on an input electric signal;
a second substrate that is bonded to the upper face of the first substrate; and
a third substrate that is bonded to the lower face of the first substrate,
the second substrate or the third substrate having a through hole for electrically connecting the first substrate to an external electrode, and
at least the vibration unit of the first substrate being hermetically sealed by bonding the second substrate and the third substrate to the first substrate.

13. The acoustic wave device as claimed in claim 12, wherein the second substrate and the third substrate have a hollow for allowing solid vibrations of the vibration unit.

14. The acoustic wave device as claimed in claim 12, wherein at least the outer periphery of the bonding area between the first substrate and the second substrate and the outer periphery of the bonding area between the first substrate and the third substrate are covered with a mold made of a predetermined plastic or resin material.

15. The acoustic wave device as claimed in claim 12, wherein the second substrate and the third substrate are insulating substrates.

16. The acoustic wave device as claimed in claim 12, wherein the second substrate and the third substrate are made of at least one of silicon, glass, ceramics, and plastic.

17. The acoustic wave device as claimed in claim 12, further comprising
a fourth substrate that has a wire for transmitting the electric signal,
wherein
the second substrate or the third substrate is face-down bonded to the fourth substrate, and the wire is electrically connected to the vibrator by virtue of a metal bump that is put into the through hole.

18. The acoustic wave device as claimed in claim 17, wherein the fourth substrate is made of ceramics or is formed by a semiconductor chip.

19. A method of producing an acoustic wave device, comprising the step of
bonding a second substrate to a first substrate, the first substrate having a vibration unit that generates solid vibrations based on input electric signal and an electrode pad unit that introduces the electric signal into the vibration unit, the second substrate having through holes for electrically connecting the electrode pad unit to external electrodes, and the second substrate being bonded to a face of the first substrate on which the vibration unit is formed, to thereby hermetically seal at least the vibration unit of the first substrate.

20. The method as claimed in claim 19, further comprising the step of
forming a peripheral metal layer on the first substrate, the peripheral metal layer surrounding at least the vibration unit,
wherein
the second substrate is bonded to the peripheral metal layer and/or the electrode pad unit, to thereby hermetically seal the vibration unit.

21. The method as claimed in claim 19, further comprising the step of
forming a hollow on the second substrate, the hollow allowing solid vibrations of the vibration unit.

22. The method as claimed in claim 20, further comprising the step of
forming a metal film on the electrode pad unit and/or the peripheral metal layer,
wherein
the second substrate is bonded to the metal film, to thereby hermetically seal the vibration unit.

23. The method as claimed in claim 19, further comprising the step of
covering at least the outer periphery of the bonding area between the first substrate and the second substrate with a mold that is made of a predetermined plastic or resin material.

24. The method as claimed in claim 19, further comprising the steps of:
putting metal bumps into the through holes; and
face-down bonding the face of the second substrate on which the through holes are formed, to the face of the third substrate having wires for transmitting the electric signal, to thereby electrically connect the wires to the electrode pad unit.

25. The method as claimed in claim 19, wherein the first substrate has a plurality of vibration units and a plurality of electrode pad units formed thereon,
the method further comprising the step of
cutting out a plurality of acoustic wave devices one by one, the plurality of acoustic wave devices having been formed through the foregoing step.

26. The method as claimed in claim 24, wherein:
the first substrate has a plurality of vibration units and a plurality of electrode pad units formed thereon, the second substrate being bonded to the first substrate; and
the face of the second substrate on which the through holes are formed is face-down bonded to the face of the third substrate on which the wires each paired with a corresponding one of the electrode pad units are formed,
the method further comprising the step of
cutting out a plurality of acoustic wave devices one by one, the plurality of the acoustic wave devices having been formed through the foregoing steps.

27. A method of producing an acoustic wave device, comprising the steps of:
bonding a second substrate onto the upper face of a first substrate on which a vibrator is formed, the vibrator generating solid vibrations based on an input electric signal; and
bonding a third substrate to the lower face of the first substrate, the third substrate having a through hole for connecting the vibrator to an external electrode,
at least the vibrator of the first substrate being hermetically sealed through the foregoing steps.

28. The method as claimed in claim 27, further comprising the step of
forming a hollow in the second substrate and the third substrate, the hollow allowing solid vibrations of the vibrator.

29. The method as claimed in claim 27, further comprising the step of
covering at least the outer periphery of the bonding area between the first substrate and the second substrate and the outer periphery of the bonding area between the first substrate and the third substrate with a mold that is made of a predetermined plastic or resin material.

30. The method as claimed in claim 27, further comprising the steps of:
putting a metal bump into the through hole;
face-down bonding the face of the third substrate on which the through hole is formed, to a fourth substrate having wires for transmitting the electric signal, to thereby electrically connect the wires to the first substrate.

31. The method as claimed in claim 27, wherein the first substrate, to which the second substrate and the third substrate are bonded, has a plurality of vibrators formed thereon,
the method further comprising the step of
cutting out a plurality of acoustic wave devices one by one, the plurality of acoustic wave devices having been formed through the foregoing steps.

32. The method as claimed in claim 30, wherein:
the first substrate, to which the second substrate and the third substrate are bonded, has a plurality of vibrators formed thereon; and
the face of the third substrate on which the through hole is formed is face-down bonded to the fourth substrate having the wires each paired with each corresponding one of the vibrators,
the method further comprising the step of
cutting out a plurality of acoustic wave devices one by one, the plurality of acoustic wave devices having been formed through the foregoing steps.
